(19) United States
(12) Patent Application Publication
(10) Pub. No.: US 2024/0327202 A1
(43) Pub. Date: Oct. 3, 2024

(54) ELECTRONIC CIGARETTE

(71) Applicant: AAC ACOUSTIC TECHNOLOGIES (SHENZHEN) CO., LTD., Shenzhen (CN)

(72) Inventors: Jinyang Li, Shenzhen (CN); Tao Fang, Shenzhen (CN); Rui Zhang, Shenzhen (CN)

(21) Appl. No.: 18/399,722

(22) Filed: Dec. 29, 2023

Related U.S. Application Data
(63) Continuation of application No. PCT/CN2023/085987, filed on Apr. 3, 2023.

(51) Int. Cl. B81B 7/00; A24F 40/40; A24F 40/51; H05K 7/14

(52) U.S. Cl. CPC B81B 7/0061; A24F 40/40; A24F 40/51; H05K 7/1427; B81B 2201/0257; B81B 2203/0127; B81B 2207/012

(57) ABSTRACT

An electronic cigarette includes a cigarette body housing and a MEMS sensor located in the cigarette body housing. The MEMS sensor includes a shell with a receiving cavity, a MEMS Die with a back cavity received in the receiving cavity, an ASIC Die located in the receiving cavity and electrically connected to the MEMS Die, a first waterproof breathable membrane fixed to the shell and completely covering the first acoustic hole, and a second waterproof breathable membrane fixed to the shell and completely covering the second acoustic hole. The shell includes a first acoustic hole and a second acoustic hole penetrating the shell and communicating with the receiving cavity and an outside. Compared with the related art, the MEMS sensor disclosed by the present disclosure provides a MEMS Die with good performance.

### TECHNICAL FIELD

The present disclosure relates to a field of sensor technology, in particular to an electronic cigarette.

### BACKGROUND

With the rapid development of acoustic-electric conversion technology, the application of loudspeaker and microphone have been gradually applied to various industries, such as communication equipment, household sound control appliances and entertainment equipment.

Among them, microphone is a transducer that converts sound airflow or vibration frequency into electronic signals, and the microphone or MEMS sensor formed based on MEMS Die is now widely used due to its advantages of small size, light weight, low cost, low power consumption, high reliability and easy integration.

The application of MEMS sensors to electronic cigarettes belong to a conventional application method, specifically, the MEMS sensors are mounted on the cigarette body housing, so that the electronic cigarettes can sense the vibration changes of the airflow to make corresponding behaviors.

The MEMS sensor in the electronic cigarette in the related art mainly includes a housing with an accommodation space, and an AISC Die and a MEMS Die that are housed in the housing and connected to each other, wherein the housing is provided with acoustic holes or airflow holes running through it.

Although the MEMS sensor of the electronic cigarette in the related art can communicate the airflow signal to the MEMS Die through the acoustic holes to cause the vibration of the diaphragm in the MEMS Die so as to realize the conversion between the airflow signal and the electronic signal, since the acoustic holes are set up through the casing, the impurities, such as water, oil, dust, and aerosols, will enter into the MEMS Die from the acoustic holes, which will lead to the degradation of the performance or damage of the MEMS Die.

Thus, it is necessary to provide a MEMS sensor to solve the problem.

### SUMMARY

In view of the above, an objective of the present disclosure is to provide an electronic cigarette with good performance.

In order to achieve the objective mentioned above, the present disclosure discloses an electronic cigarette including a cigarette body housing and a MEMS sensor located in the cigarette body housing. The MEMS sensor includes a shell with a receiving cavity, a MEMS Die with a back cavity received in the receiving cavity, an ASIC Die located in the receiving cavity and electrically connected to the MEMS Die, a first waterproof breathable membrane fixed to the shell and completely covering the first acoustic hole, and a second waterproof breathable membrane fixed to the shell and completely covering the second acoustic hole. The shell includes a first acoustic hole and a second acoustic hole penetrating the shell and communicating with the receiving cavity and an outside.

As an improvement, the first waterproof breathable membrane is fixed to an inside of the shell.

As an improvement, the second acoustic hole and the first acoustic hole are provided on opposite sides of the housing respectively, and the second acoustic hole is provided orthogonally to the back cavity.

As an improvement, the second waterproof breathable membrane is fixed to an inside of the shell.

As an improvement, there are a plurality of ASIC Dies, and each of the ASIC Dies is connected to the MEMS Die.

As an improvement, the shell comprises a circuit board and an upper cover assembled with the circuit board, the upper cover is jointly enclosed with the circuit board to form the receiving cavity, the ASIC Die is fixed to the circuit board and electrically connected to the circuit board, the MEMS Die is fixed to the circuit board and electrically connected to the circuit board, the first acoustic hole is provided on the upper cover, the second acoustic hole is provided on the circuit board.

As an improvement, the upper cover and the circuit board are jointly enclosed to form the receiving cavity which is rectangular.

As an improvement, the ASIC Die is electrically connected to the circuit board via a connecting wire, the MEMS Die is electrically connected to the ASIC Die and the circuit board via connecting wires respectively.

### BRIEF DESCRIPTION OF DRAWINGS

FIG. 1 is an isometric view of an electronic cigarette in accordance with an exemplary embodiment of the present disclosure.

FIG. 2 is a cross-sectional view of a MEMS sensor of the electronic cigarette in accordance with an exemplary embodiment of the present disclosure.

### DESCRIPTION OF EMBODIMENTS

The technical solutions in embodiments of the present disclosure will be described clearly and completely below with reference to the accompanying drawings in the embodiments of the present disclosure.

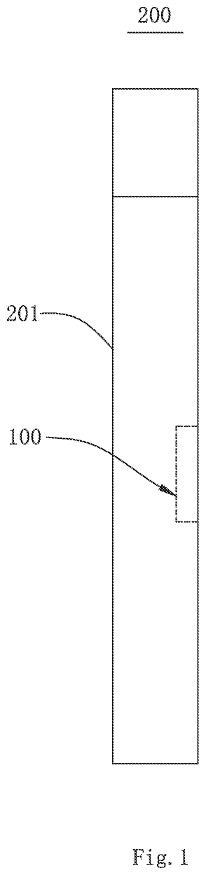

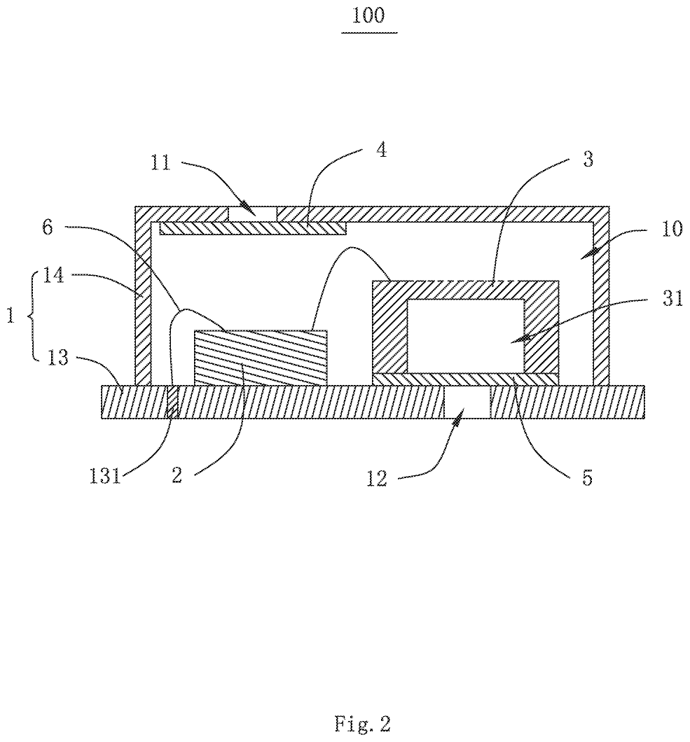

As shown in FIG. 1 and FIG. 2, the present disclosure discloses an electronic cigarette 200 including a cigarette body housing 201 and a MEMS sensor 100 accommodated in the cigarette body housing 201. The MEMS sensor 100 includes a shell 1 with a receiving cavity 10, and an ASIC Die 2 and a MEMS Die 3 located in the receiving cavity 10, the ASIC Die 2 and the MEMS Die 3 are electrically connected, and the MEMS Die 3 is provided with a back cavity 31. The shell 1 is provided with a first acoustic hole 11 penetrating the shell 1 and communicating with the receiving cavity 10 and an outside. The MEMS sensor 100 further includes a first waterproof breathable membrane 4 fixed to the shell 1 and completely covering the first acoustic hole 11.

The MEMS Die 3 is a capacitive MEMS Die 3; the AISC Die 2 may include one or a plurality of AISC Dies, and when the AISC Die 2 includes a plurality of AISC Dies, the plurality of AISC Dies 2 are set in a spaced apart manner and are electrically coupled to the MEMS Die 3 respectively. In this embodiment, there is only one AISC chip 2.

The shell 1 includes a circuit board 13 (PCB) and an upper cover 14 assembled with the circuit board 13, the upper cover 14 is jointly enclosed with the circuit board 13 to form the receiving cavity 10; the AISC Die 2 is fixed to the circuit board 13 and electrically connected to a circuit 131 of the circuit board 13, and the MEMS Die 3 is fixed to the circuit board 13 and electrically connected to the circuit 131 of the circuit board 13; in particular, the upper cover 14 is made of a metallic material; and the first acoustic hole 11 is provided in the upper cover 14.

The upper cover 14 and the circuit board 13 are jointly enclosed to form the receiving cavity 10 which is rectangular. According to the actual demand, the receiving cavity 10 formed by the upper cover 14 and the circuit board 13 could be designed into other shapes, such as an oval, a trapezoid, and so on.

The first waterproof breathable membrane 4 is fixed to an inside of the shell 1, in this embodiment, the first waterproof breathable membrane 4 is fixed to an inside of the upper cover 14. An outer side of the shell 1 is the side of the shell 1 away from the receiving cavity 10, and the inner side of the shell 1 is the side of the shell 1 close to the receiving cavity 10; while the outer side of the upper cover 14 is the side of the upper cover 14 away from the receiving cavity 10, and the inner side of the upper cover 14 is the side of the upper cover 14 close to the receiving cavity 10.

The ASIC Die 2 is electrically connected to the circuit board 13 via the circuit 131, the MEMS Die 3 is electrically connected to the ASIC Die 2 and the circuit board 13 via the circuit 131 respectively. The ASIC Die 2 is electrically connected or in communicative connection with the circuit 131 of the circuit board 13, the MEMS Die 3 is electrically connected or in communicative connection with the ASIC Die 2.

In addition, the shell 1 is further provided a second acoustic hole 12 penetrating thereon and communicating with the outside and the receiving cavity 10, the second acoustic hole 12 and the first acoustic hole 11 are provided on opposite sides of the shell 1, the second acoustic hole 12 is provided orthogonally to the back cavity 31. The MEMS sensor 100 further includes a second waterproof breathable membrane 5 fixed to the shell 1, the second waterproof breathable membrane 5 completely covers the second acoustic hole 12. The second sound hole 12 is provided in the circuit board 13 of the shell 1.

The second acoustic hole 12 and the first acoustic hole 11 are both used to enable the airflow signal to be communicated to the MEMS Die 3 through the shell 1; the second waterproof breathable membrane 5 and the first waterproof breathable membrane 4 are both used to permeate through the airflow and intercept impurities such as water, oil, and dust, and they are both made of a new type of polymer waterproof material.

The second waterproof breathable membrane 5 is fixed to the inside of the shell 1, the second waterproof breathable membrane 5 is fixed to an inside of the circuit board 13. An outer side of the circuit board 13 is the side of the circuit board 13 away from the receiving cavity 10, and the inner side of the circuit board 13 is the side of the circuit board 13 close to the receiving cavity 10, when the second waterproof breathable membrane 5 is fixed to the inside of the circuit board 13, the second waterproof breathable membrane 5 is fixed between the MEMS Die 3 and the circuit board 13.

The acoustic-electric conversion process of the MEMS sensor 100 in this embodiment is as follows: the airflow signal enters the receiving cavity 10 from the first acoustic hole 11 through the first waterproof breathable membrane 4, or/and from the second acoustic hole 12 through the second waterproof breathable membrane 5 to cause vibration of the diaphragm of the MEMS Die 3, so as to realize the conversion of the airflow signal to the electronic signal.

Compared with the related art, the MEMS sensor 100 in the electronic cigarette 200 of the present embodiment is provided with a first waterproof breathable membrane 4 at the location of the first acoustic hole 11, so that impurities such as water, oil, dust, and aerosols can be intercepted by the first waterproof breathable membrane 4 to avoid impurities from entering into the MEMS Die 3 through the first acoustic hole 11, resulting in degradation of the performance of or damage to the MEMS Die 3. In addition, the location of the second acoustic hole 12 can likewise intercept impurities such as water, oil, dust and aerosols through the second waterproof breathable membrane 5, in order to avoid impurities from entering into the MEMS Die 3 from the second acoustic hole 12, resulting in degradation of performance or damage of the MEMS Die 3.

The above descriptions are merely some of the embodiments of the present disclosure. It should be pointed out that for those of ordinary skill in the art, improvements can be made without departing from the inventive concept of the present disclosure, shall fall within the scope of the present disclosure.

What is claimed is:

1. An electronic cigarette, comprising:
a cigarette body housing; and
a MEMS sensor located in the cigarette body housing, comprising:
a shell with a receiving cavity, comprising a first acoustic hole and a second acoustic hole penetrating the shell and communicating with the receiving cavity and an outside;
a MEMS Die with a back cavity received in the receiving cavity;
an ASIC Die located in the receiving cavity and electrically connected to the MEMS Die;
a first waterproof breathable membrane fixed to the shell and completely covering the first acoustic hole; and
a second waterproof breathable membrane fixed to the shell and completely covering the second acoustic hole.

2. The electronic cigarette described as claim 1, wherein the first waterproof breathable membrane is fixed to an inside of the shell.

3. The electronic cigarette described as claim 1, wherein the second acoustic hole and the first acoustic hole are provided on opposite sides of the housing respectively, and the second acoustic hole is provided orthogonally to the back cavity.

4. The electronic cigarette described as claim 1, wherein the second waterproof breathable membrane is fixed to an inside of the shell.

5. The electronic cigarette described as claim 1, wherein there are a plurality of ASIC Dies, and each of the ASIC Dies is connected to the MEMS Die.

6. The electronic cigarette described as claim 1, wherein the shell comprises a circuit board and an upper cover assembled with the circuit board, the upper cover is jointly enclosed with the circuit board to form the receiving cavity, the ASIC Die is fixed to the circuit board and electrically connected to the circuit board, the MEMS Die is fixed to the circuit board and electrically connected to the circuit board, the first acoustic hole is provided on the upper cover, the second acoustic hole is provided on the circuit board.

7. The electronic cigarette described as claim 6, wherein the upper cover and the circuit board are jointly enclosed to form the receiving cavity which is rectangular.

8. The electronic cigarette described as claim 6, wherein the ASIC Die is electrically connected to the circuit board via a connecting wire, the MEMS Die is electrically connected to the ASIC Die and the circuit board via connecting wires respectively.
